(19) United States
(12) Patent Application Publication
(10) Pub. No.: US 2008/0285214 A1
(43) Pub. Date: Nov. 20, 2008

(54) ELECTRONIC APPARATUS

(75) Inventors: Yoshinori Kohmoto, Ome-shi (JP); Hironori Motoe, Ome-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/117,594

(22) Filed: May 8, 2008

(30) Foreign Application Priority Data
May 18, 2007 (JP) 2007132921

(51) Int. Cl. H05K 5/02

(52) U.S. Cl. 361/680

(57) ABSTRACT

According to one embodiment, an electronic apparatus is provided with a keyboard section provided on a main body unit, a display unit, and a hinge section for rotatably coupling the display unit to the main body unit. The keyboard section includes a plurality of keys to which inputting functions different from each other are allocated. The electronic apparatus is switchable a first usage state, in which the main body unit is to be placed on a desktop, a second usage state, in which the electronic apparatus is to be held with a hand. The keyboard section is constructed and arranged, when the electronic apparatus is used in the second usage state, the allocation of the inputting functions to the keys is electrically switched in such a manner that correspondence relationships between the fingertips and the inputting functions in the first usage state are maintained in the second usage state.

### CROSS-REFERENCE TO RELATED APPLICATIONS

This application is based upon and claims the benefit of priority from Japanese Patent Application No. 2007-132921, filed May 18, 2007, the entire contents of which are incorporated herein by reference.

### BACKGROUND

1. Field

One embodiment of the present invention relates to, for example, an electronic apparatus which can also be used in a hand-held state in addition to a desktop use.

2. Description of the Related Art

In recent years, many small-sized electronic apparatuses of such a size that can be carried by hand have been produced. For example, Jpn. Pat. Appln. KOKAI Publication No. 8-202473 discloses an electronic apparatus which is operated in a hand-held state, where it is held with both hands of a user. This electronic apparatus is provided with a main body unit including a display screen, and a keyboard section divided into right and left parts.

When the electronic apparatus described above is used in normal state, the main body unit and the keyboard section are opened and placed on a desktop. When this electronic apparatus is used in the hand-held state, the right and left parts of the keyboard section are respectively turned by 90° and the main body unit and the keyboard section are folded in a back-to-back state. This makes it possible to perform a key input operation by using the keyboard section exposed on the backside of the apparatus while viewing the display screen in the hand-held state.

Incidentally, in the electronic apparatus described above, when a usage state is changed from the normal state where the apparatus is placed on a desktop to the handheld state where the apparatus is held with both hands, switching of the keyboard section is performed by structurally rotating the right and left parts of the keyboard section. That is, the electronic apparatus involves a complicated casing structure for enabling rotation of the right and left parts of the keyboard section. Employment of such a complicated casing structure is not so advantageous for an electronic apparatus for which further downsizing is desired.

Further, in the electronic apparatus described above, the orientations of the right and left parts of the keyboard section in the normal state and those in the hand-held state differ from each other by 90°, and hence it is possible that a user may feel a sense of discomfort.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view showing a first usage state of an electronic apparatus according to a first embodiment of the present invention;

FIG. 2 is an exemplary plan view showing the first usage state of the electronic apparatus shown in FIG. 1;

FIG. 3 is an exemplary perspective view showing a transformation process of the electronic apparatus shown in FIG. 1;

FIG. 4 is an exemplary perspective view showing a second usage state of the electronic apparatus shown in FIG. 1;

FIG. 5 is an exemplary plan view showing the second usage state of the electronic apparatus shown in FIG. 1;

FIG. 6 is an exemplary rear view (i.e., backside view) showing the second usage state of the electronic apparatus shown in FIG. 1;

FIG. 7 is an exemplary plan view showing a first usage state of an electronic apparatus according to a second embodiment of the present invention;

FIG. 8 is an exemplary plan view showing a second usage state of the electronic apparatus shown in FIG. 7;

FIG. 9 is an exemplary plan view showing a first usage state of an electronic apparatus according to a third embodiment of the present invention; and

FIG. 10 is an exemplary plan view showing a second usage state of the electronic apparatus shown in FIG. 9.

### DETAILED DESCRIPTION

Various embodiments according to the invention will be described hereinafter with reference to the accompanying drawings. In general, according to one embodiment of the invention, an electronic apparatus is provided with a main body unit; a keyboard section provided on the main body unit, and including a plurality of keys to which inputting functions different from each other are allocated; a display unit including a display screen; and a hinge section rotatably coupling the display unit to the main body unit. The electronic apparatus is switchable between a first usage state, in which the display unit is raised from the main body unit and the keyboard section is to be operable with the main body unit being placed on a desktop, and a second usage state, in which the main body unit and the display unit are folded back to back with each other, the electronic apparatus is to be held with a hand of a user with the display screen being directed to the user, and the keyboard section is exposed on a backside of the electronic apparatus and is to be operable with fingertips of the hand. The keyboard section is constructed and arranged such that, when the electronic apparatus is used in the second usage state, the allocation of the inputting functions to the keys is electrically switched in such a manner that correspondence relationships between the fingertips and the inputting functions in the first usage state are maintained in the second usage state.

An embodiment of the present invention will be described below on the basis of a drawing of an example in which the present invention is applied to a mobile electronic apparatus such as a hand-held computer. Incidentally, in this description, the front side (i.e., user side) is defined as “front”, the back side viewed from the user is defined as “rear”, the left side viewed from the user is defined as “left”, and the right side viewed from the user is defined as “right”.

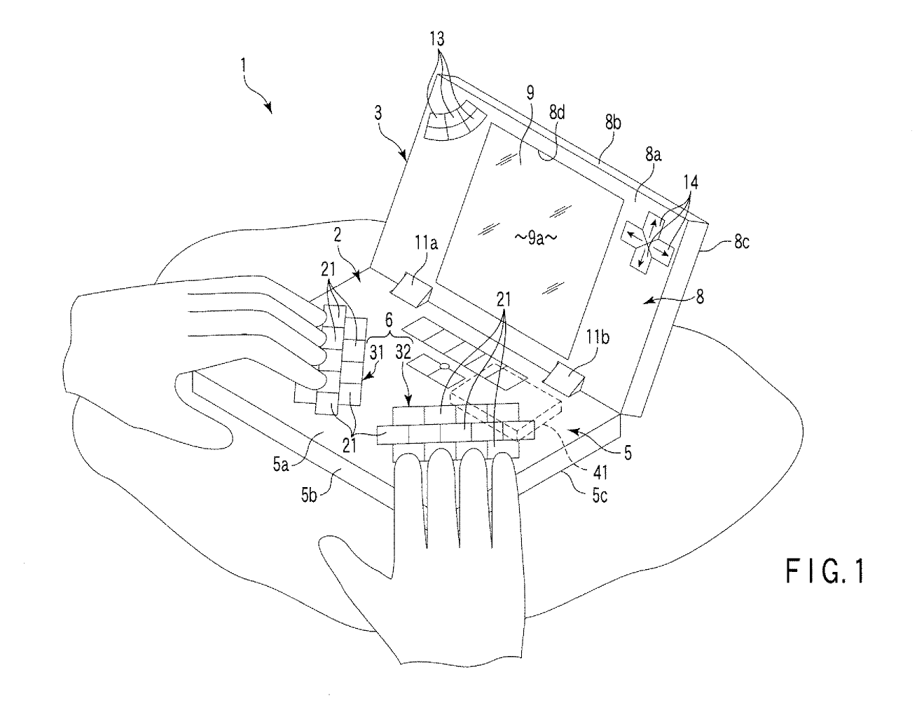

FIGS. 1 to 6 disclose an electronic apparatus 1 according to a first embodiment of the present invention. As shown in FIG. 1, the electronic apparatus 1 is provided with a main body unit 2 (i.e., apparatus main body), and a display unit 3. The main body unit 2 includes a main body casing 5. The main body casing 5 is formed into a box-like shape including an upper wall 5a, a peripheral wall 5b, and a lower wall 5c. On the upper wall 5a, a keyboard section 6 is exposed. Inside the main body casing 5, a circuit board and the like (not shown) are mounted, whereby the main body unit 2 is provided with an information processing function.

The display unit 3 is provided with a display unit casing 8, and a display device 9 contained in this display unit casing 8. The display unit casing 8 is formed into a box-like shape including a front wall 8a, a peripheral wall 8b, and a rear wall 8c. An example of the display device 9 is a liquid crystal display panel. The display device 9 includes a display screen 9a. The front wall 8a of the display unit casing 8 includes an opening section 8d for exposing the display screen 9a to the outside.

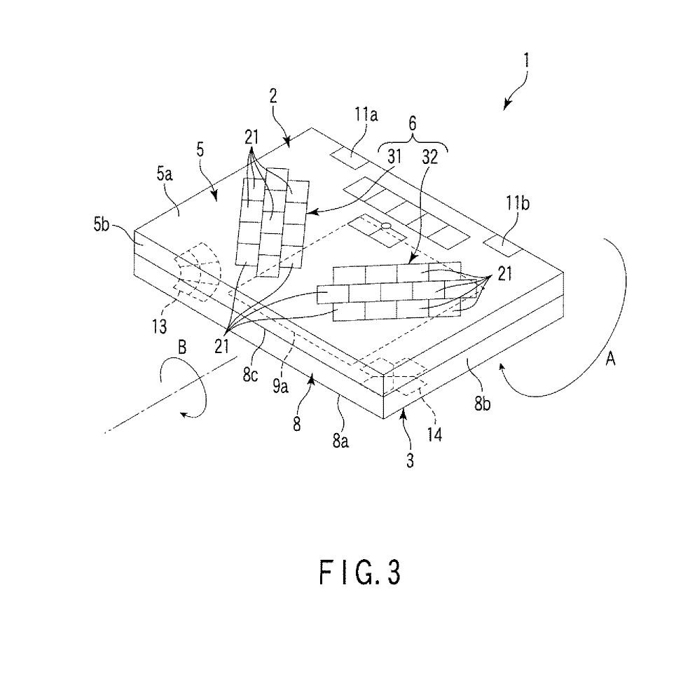

As shown in FIG. 1, between the display unit 3 and the main body unit 2, for example, a pair of hinge sections 11a and 11b, are provided. The hinge sections 11a and 11b rotatably couple an end part of the display unit 3 to a rear end part of the main body unit 2. By being supported by the hinge sections 11a and 11b, the display unit 3 can be turned among a closed position, in which the display unit 3 is laid on top of the main body unit 2 so as to cover the upper wall 5a of the main body unit 2, a first opened position (see FIG. 1), in which the display unit 3 is raised from the main body unit 2 so as to expose the upper wall 5a and the display screen 9a, and a second opened position (see FIG. 3), in which the display unit 3 is folded back toward the backside of the main body unit 2, and is laid on the main body unit 2 so as to cover the lower wall 5c of the main body unit 2.

As shown in FIG. 1, in regions adjacent to the display screen 9a at an end part of the display unit 3 opposite to the end part thereof coupled to the hinge sections 11a and 11b, for example, a plurality of control keys 13 and 14 are mounted. Each of keys 13, 14 is an example of “another key” of the invention. To the control keys 13 provided at the upper left side end of the display unit 3, functions of, for example, an Enter key, space key, Back Space key, shift key, Esc key, Ctrl key, and the like are allocated. To the control keys 14 provided at the upper right side end of the display unit 3, functions of, for example, arrow keys are allocated. Incidentally, functions allocated to the control keys 13 and 14 are not limited to the examples described above, and various functions can be allocated to them. Further, the control keys 13 and 14 may be omitted.

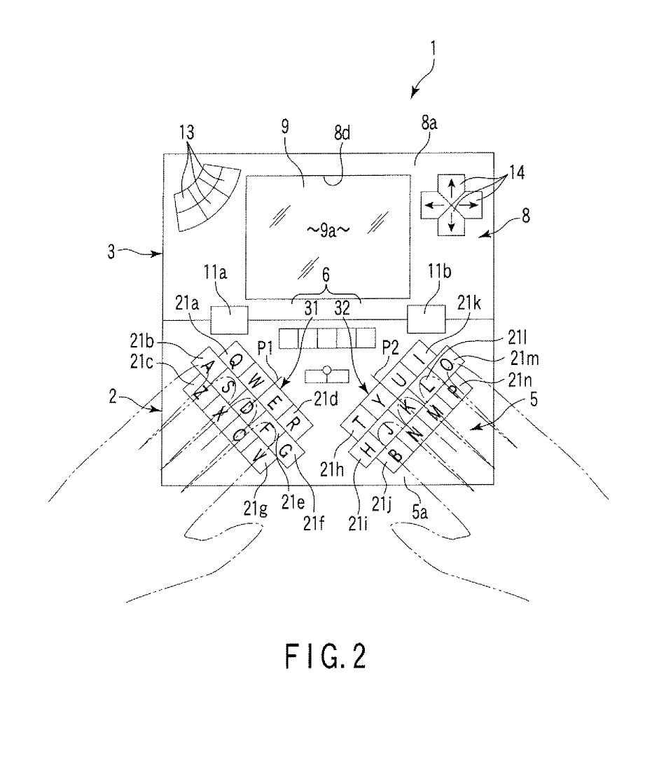

As shown in FIG. 1, the keyboard section 6 is provided on the main body unit 2, and includes a plurality of keys 21. To the plural keys 21, inputting functions different from each other are allocated. The expression “inputting functions different from each other” refers to, for example, inputting functions of alphabetical characters. The keyboard section 6 includes, for example, twenty-six keys 21 corresponding to the English alphabet, and these keys are arranged in a form conforming to the key arrangement standardized in, for example, JIS or the like as shown in FIG. 2.

The keyboard section 6 is divided into a first key group 31 for the left-hand operation, and a second key group 32 for the right-hand operation. As shown in FIG. 2, each of the first and second key groups 31 and 32 is divided into, for example, three rows. In the rows of each the first and second key groups 31 and 32, for example, four, five, and four keys 21 are arranged in order from the rear side.

The first and second key groups 31 and 32 are provided in such a manner that the number of keys 21 and the mounting arrangement of the keys 21 are identical with each other. Incidentally, in this description, the expression “mounting arrangement of the keys” refers to the physical (i.e., structural) mounting arrangement of the keys, and the term “key allocation arrangement” and “key arrangement” refer to an arrangement of inputting functions allocated to the keys.

As shown in FIG. 2, the mounting arrangement of the first key group 31 is symmetrical with respect to a straight line P1 passing through the center of the first key group 31, and extending in a direction perpendicular to the longitudinal direction of the first key group 31. The mounting arrangement of the second key group 32 is symmetrical with respect to a straight line P2 passing through the center of the second key group 31, and extending in the direction perpendicular to the longitudinal direction of the second key group 32.

Each of the first and second key groups 31 and 32 is arranged oblique in such a manner that with an increase in the distance on the main body unit 2 from the end part (i.e., the rear end part) coupled to the hinge sections 11a and 11b toward the end part (i.e., the front end part) opposite to the rear end part, each of the first and second key groups 31 and 32 becomes closer to the center portion of the main body unit 2. As a result of this, the user's hands adopt a posture such that the wrists are further apart than the fingers, which are more closely bunched together, which helps in operating the small-sized keyboard 6.

This electronic apparatus 1 realizes a desktop computer and a hand-held computer by one system. That is, the electronic apparatus 1 can be switched (i.e., transformed) from/to a form for the desktop usage state to/from a form for the hand-held usage state in accordance with the usage and the environment, thereby providing high convenience.

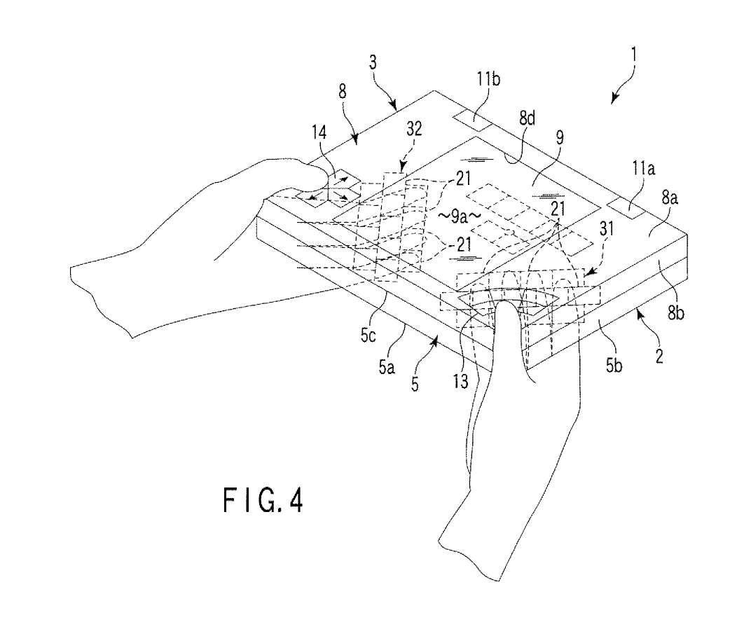

The electronic apparatus 1 can be carried with the display unit 3 rotated to the closed position, and is switchable between a first usage state (see FIG. 1) in which the apparatus 1 is to be used on the desktop and a second usage state (see FIG. 4) in which the apparatus 1 is to be used while being held with both hands of a user.

More specifically, in the first usage state (i.e., the desktop usage state), as shown in FIG. 1, the display unit 3 is raised from the main body unit 2, and the main body unit 2 is placed on the desktop. The user can then operate the keyboard section 6 exposed on the upper surface side of the main body unit 2 with both his/her hands.

FIG. 3 shows the one example of transformation from the first usage state to the second usage state. In the transformation from the first usage state to the second usage state, first, the display unit 3 is folded back to the backside of the main body unit 2 in the direction as shown by an arrow A in FIG. 3, and the main body unit 2 and the display unit 3 are folded back to back with each other. Incidentally, the expression “back to back with each other” implies that the wall surface (i.e., the surface of the lower wall 5c) of the main body unit 2 opposite to the keyboard section 6 and the wall surface (i.e., the surface of the rear wall 8c) of the display unit 3 opposite to the display screen 9a are opposed to each other.

Almost simultaneously with the folding of the main body unit 2 and the display unit 3 back to back with each other, the electronic apparatus 1 is turned upside down in the direction of an arrow B in FIG. 3 such that the display screen 9a is directed to the user. As a result of this, the electronic apparatus I is switched to a form for the second usage state (i.e., the hand-held usage state) shown in FIG. 4. In this second usage state, the electronic apparatus 1 is used in a state where the end part opposite to the end part coupled to the hinge sections 11a and 11b is closer to the user than the end part coupled to the hinge sections 11a and 11b.

In this second usage state, the display screen 9a is exposed on the upper side of the electronic apparatus 1, and the keyboard section 6 is exposed on the backside (i.e., lower side) of the electronic apparatus 1. The user can operate the electronic apparatus 1 by holding the electronic apparatus 1 with both hands, and performing blind touch-typing on the keyboard section 6 exposed on the backside of the electronic apparatus 1 with the fingertips of the fingers of both the hands from the index finger to the little finger. Incidentally, in this second usage state, the first key group 31 corresponds to the right hand of the user, and the second key group 32 corresponds to left hand of the user.

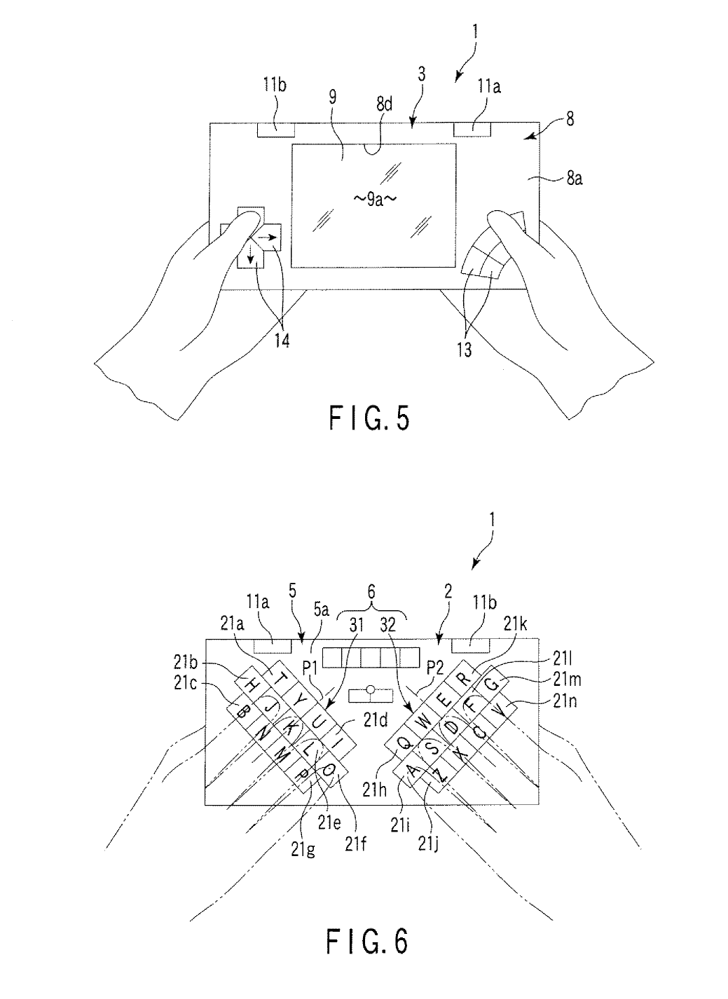

Further, as shown in FIG. 5, in this second usage state, the control keys 13 and 14 are arranged at the front side (i.e., user side) end part of the upper side of the electronic apparatus 1. The user can operate the control keys 13 and 14 located at the right and left lateral parts of the display screen 9a by using, for example, both thumbs. With the electronic apparatus 1 associated with this embodiment, even in the second usage state, the user's hands adopt a posture such that, when the user uses the first and second key groups 31 and 32, the wrists are further apart than the fingers, which are more closely bunched together, which helps in operating the small-sized keyboard 6.

Next, allocation of the inputting functions to the keys 21 of the keyboard section 6 will be described below.

FIG. 2 shows an example of allocation of the inputting functions to the keys 21 in the first usage state. In this first usage state, the user can use his or her fingers for touch-typing, i.e., corresponding each finger to certain keys, to input letters of the alphabet. That is, the user can determine specific fingertips undertaking operations of specific keys 21 by himself or herself, whereby the user can construct a correspondence relationship between a specific fingertip and a specific inputting function.

It is assumed that for example, specific keys 21a, 21b, and 21c to which inputting functions of characters Q, A, and z are allocated are operated with the small finger of the left hand. As a result of this, the inputting functions of the characters Q, A, and Z correspond to the small finger of the left hand. It is also assumed that for example, specific keys 21d, 21e, 21f, and 21g to which inputting functions of the characters R, F, G, and V are allocated are operated with the index finger of the left hand. As a result of this, the inputting functions of the characters R, F, G, and V correspond to the index finger of the left hand.

In the electronic apparatus 1, when the apparatus 1 is used in the second usage state, the allocation of the inputting functions to the keys 21 is electrically switched. This switching will be described below in detail. The allocation of the inputting functions to the keys 21 is switched so that the same fingertip can undertake the same inputting functions both in the first usage state and the second usage state.

In other words, inputting functions are newly allocated to the keys 21 so that the correspondence relationships between the fingertips and the inputting functions of the respective characters in the first usage state are maintained in the second usage state. In this embodiment, the switching of the allocation of the inputting functions to the keys is performed by replacing the key allocation arrangement of the first key group 31 and the key allocation arrangement of the second key group 32 with each other.

FIG. 6 shows the allocation of the inputting functions to the respective keys 21 in the second usage state. Incidentally, FIG. 6 is a view of the electronic apparatus 1 viewed from the backside of the electronic apparatus 1. In this second usage state, the respective fingertips correspond to the same characters as in the first usage state.

For example, to the specific keys 21h, 21i, and 21j which can be operated with the little finger of the left hand, the inputting functions of the characters Q, A, and Z are allocated, respectively from the rear side. As a result of this, the correspondence relationships between the inputting functions of the characters Q, A, and Z and the little finger of the left hand are maintained. For example, to the specific keys 21k, 21l, 21m, and 21n which can be operated with the index finger of the left hand, the inputting functions of the characters R, F, G, and V are allocated, respectively from the rear side. As a result of this, the correspondence relationships between the inputting functions of the characters R, F, G, and V and the index finger of the left hand are maintained.

Incidentally, the expression that the allocation of the inputting functions to the keys 21 is “electrically switched” implies that the allocation is switched by software without any structural change. As shown in FIG. 1, the main body unit 2 includes a control section 41. The control section 41 allocates the specific inputting functions to the respective keys 21 of the keyboard section 6.

Further, the control section 41 rotates the display direction of the display screen 9a 180° when the electronic apparatus 1 is switched from the form for the first usage state to the form for the second usage state. This rotation of the display screen 9a and the switching of the allocation of the inputting functions to the keys 21 may be automatically performed when the electronic apparatus 1 is switched from the form for the first usage state to the form for the second usage state, or may be manually performed by operating a changeover switch.

With such an electronic apparatus 1, ease of use of the electronic apparatus is improved by a simple structure. That is, when the electronic apparatus 1 is used in the second usage state, if the allocation of the inputting functions to the respective keys 21 is switched, and the correspondence relationships between the fingertips and the inputting functions in the first usage state are also maintained in the second usage state, the user can input the same character with the same fingertip in both the first usage state and the second usage state, and hence the electronic apparatus 1 becomes easier to use. That is, even when the user uses the electronic apparatus 1 in the second usage state, the user can operate the keyboard section 6 as in the first usage state without feeling a sense of discomfort too much.

Further, in the electronic apparatus 1, the switching of the allocation of the inputting functions to the keys 21 is performed electrically by the control section 41. As a result of this, there is neither the need for replacement of the keyboard section 6 nor the need for structural transformation such as rotation, thereby making it possible to make the structure of the main body casing 5 simple. That is, it can be said that the electronic apparatus 1 of this embodiment is improved in the usability by a simple structure. Incidentally, if the structure of the main body casing 5 can made simple, downsizing and reduction in the thickness of the electronic apparatus 1 can be realized, and hence this is advantageous for the electronic apparatus such as a hand-held computer of which further downsizing is required.

If the keyboard section is structurally rotated, the direction of the keyboard in the case where the apparatus is placed on a desktop to be used, and that in the case where the apparatus is held with both hands differ from each other, and hence the user may feel a sense of discomfort. However, with the electronic apparatus 1 associated with this embodiment, the direction of the keyboard section 6 in the first usage state, and that in the second usage state are the same, and hence the user can perform key input without feeling a sense of discomfort too much.

If the switching of the allocation of the inputting functions to the keys 21 is performed and realized by replacing the key allocation arrangement of the first key group 31 and the key allocation arrangement of the second key group 32 with each other, it is possible to avoid a complicated change in the arrangement such as turning the key allocation arrangement of each of the first and second key groups 31 and 32 or rotating the key allocation arrangement.

When the electronic apparatus 1 is used in the second usage state, where the end part thereof opposite to the end part coupled to the hinge sections 11a and 11b is closer to the user than the end part coupled to the hinge section 11a, 11b, it is possible to maintain the correspondence relationship between the fingertips and the inputting functions by such a simple change in the arrangement.

If the first and second key groups 31 and 32 are provided in such a manner that the key groups 31 and 32 are identical with each other in the number of keys 21 and the mounting arrangement of the keys 21, it is possible to replace the key allocation arrangement of the first key group 31 and the key allocation arrangement of the second key group 32 with each other without excess and deficiency. That is, there is no idle key 21 in the first or second usage state, and the keyboard section 6 can be made more compact.

If the mounting arrangement of the first key group 31 is symmetrical with respect to the straight line P1, and the mounting arrangement of the second key group 32 is symmetrical with respect to the straight line P2, the structural arrangement of the keys 21 with respect to the fingertips in both the first and second usage states. As a result of this, the sense of discomfort that the user may feel in the second usage state becomes further reduced.

Each of the first and second key groups 31 and 32 of the keyboard section 6 is arranged oblique in such a manner that with an increase in the distance on the main body unit 2 from the end part (i.e., rear end part) coupled to the hinge sections 11a and 11b toward the end part opposite to the rear end part, each of the first and second key groups 31 and 32 becomes closer to the center portion of the main body unit 2, and the first and second key groups 31 and 32 are used in a state where the end part opposite to the rear end part is on the front side at the time of use in the second usage state, the ease of use of the electronic apparatus 1 is improved. That is, with such a configuration, in both the first and second usage states, the user's hands adopt a posture such that the wrists are further apart than the fingers, which are more closely bunched together, which helps in operating the small-sized keyboard 6.

If the keys 13 and 14 are mounted in regions adjacent to the display screen 9a at an end part of the display unit 3 opposite to the end part thereof coupled to the hinge sections 11a and 11b, and the electronic apparatus 1 is used in a state where the end part opposite to the end part coupled to the hinge sections 11a and 11b is on the front side in the second usage state, the keys 13 and 14 are arranged on the front side end part of the top surface of the electronic apparatus 1 in the second usage state. With such a configuration, the user can perform an inputting operation by means of the keys 13 and 14 with the thumbs while holding the electronic apparatus 1 with both hands, and hence it can be said that the ease of use of the electronic apparatus is improved.

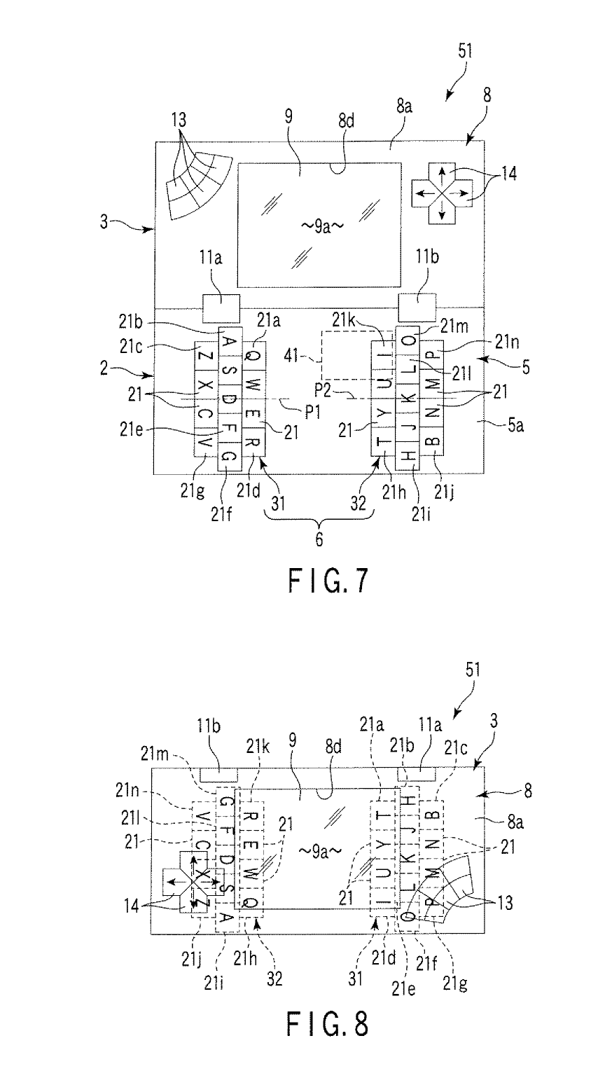

Next, an electronic apparatus 51 according to a second embodiment of the present invention will be described below with reference to FIGS. 7 and 8. Incidentally, configurations including functions which are the same as or similar to those of the electronic apparatus 1 according to the first embodiment are denoted by the same reference symbols as in the first embodiment, and a description thereof will be omitted. The electronic apparatus 51 according to the second embodiment differs from that of the first embodiment in the arrangement of a keyboard section 6, but the fundamental configuration is the same as that of the first embodiment.

The electronic apparatus 51 according to this embodiment is configured to be operated with hands extended from the right and left lateral sides at the keyboard section 6. The keyboard section 6 includes first and second key groups 31 and 32. Each of the first and second key groups 31 and 32 is divided into, for example, three rows. The first and second key groups 31 and 32 are arranged straight in the depth direction of a main body unit 2, i.e., in the direction from the front end part of the main body unit 2 to the rear end part thereof.

The transformation of the electronic apparatus 51 between a first usage state and a second usage state is the same as in the first embodiment. That is, the main body unit 2 and the display unit 3 are folded back to back with each other, and the electronic apparatus 51 is turned upside down such that a display screen 9a is directed to a user. Further, the display direction of the display screen 9a is rotated 180°. This electronic apparatus 51 is used in a state where the end part opposed the end part coupled to the hinge sections 11a and 11b is closer to the user than the end part coupled to the hinge section 11a, 11b.

In the electronic apparatus 51, when the apparatus 51 is used in the second usage state, the allocation of the inputting functions to the keys 21 is electrically switched, and the correspondence relationships between the fingertips and the inputting functions in the first usage state are also maintained in the second usage state. The switching of the allocation of the inputting functions to the keys 21 in this embodiment is performed by replacing the key allocation arrangement of the first key group 31 and the key allocation arrangement of the second key group 32 with each other, and rotating the key allocation arrangement of each of the first and second key groups 31 and 32 180°.

With the electronic apparatus 51 configured in the manner described above, like the first embodiment, the user can input the same character with the same fingertip in both the first usage state and the second usage state, and hence the ease of use of the electronic apparatus is improved by a simple structure.

If each of the first and second key groups 31 and 32 is symmetrical with respect to a straight line extending in the longitudinal direction and a straight line extending in the direction perpendicular to the longitudinal direction, excess and deficiency do not occur even when the key allocation arrangement is rotated 180°.

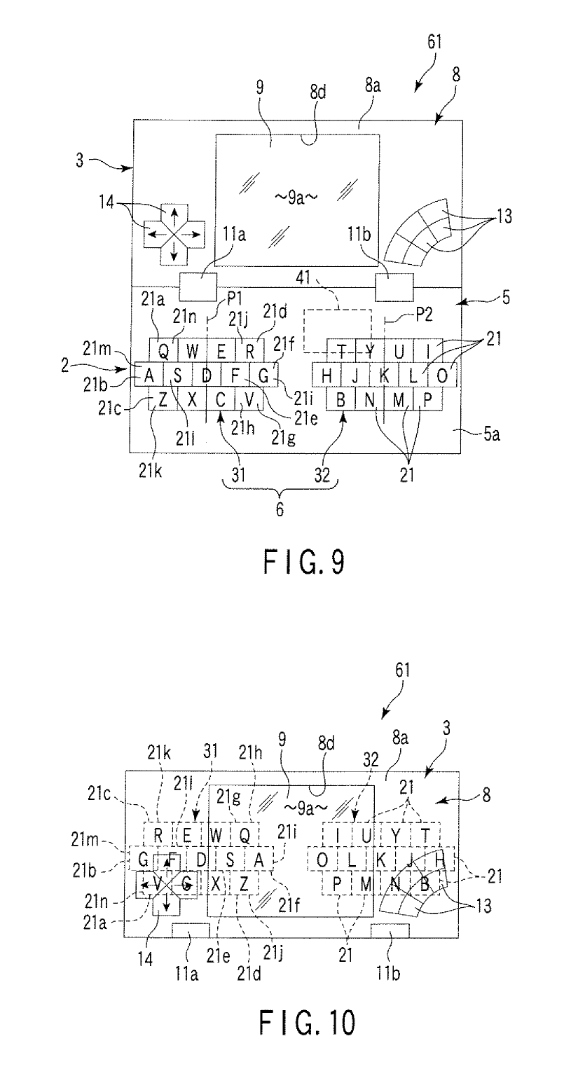

Next, an electronic apparatus 61 according to a third embodiment of the present invention will be described below with reference to FIGS. 9 and 10. Incidentally, configurations including functions which are the same as or similar to those of the electronic apparatus 1 according to the first embodiment are denoted by the same reference symbols as in the first embodiment, and a description thereof will be omitted. The electronic apparatus 61 differs from that of the first embodiment in the arrangement of a keyboard section 6, but the fundamental configuration is the same as that of the first embodiment.

The electronic apparatus 61 according to this embodiment is configured to be operated with hands extended from the front side of the electronic apparatus 61 at the keyboard section 6. The keyboard section 6 includes first and second key groups 31 and 32. Each of the first and second key groups 31 and 32 is divided into, for example, three rows. The first and second key groups 31 and 32 are arranged straight in the longitudinal direction of a main body unit 2, i.e., in the direction from the left end part of the main body unit 2 to the right end part thereof.

Transformation of the electronic apparatus 61 between a first usage state and a second usage state is performed by folding back the main body unit 2 so as to allow it to be on the backside of the display unit 3, and folding the main body unit 2 and the display unit 3 back to back with each other. Incidentally, in this embodiment, the display direction of the display screen 9a is not rotated. The electronic apparatus 61 according to this embodiment is used in the second usage state in a state where the end part coupled to the hinge sections 11a and 11b is closer to a user than the end part opposite to the end part coupled to the hinge section 11a, 11b.

In the electronic apparatus 61, when the apparatus 61 is used in the second usage state, the allocation of the inputting functions to the keys 21 is electrically switched, and the correspondence relationships between the fingertips and the inputting functions in the first usage state are also maintained in the second usage state. The switching of the allocation of the inputting functions to the keys 21 in this embodiment is performed by rotating the key allocation arrangement of each of the first and second key groups 180°.

With the electronic apparatus 61 configured in the manner described above, like the first embodiment, the user can input the same character with the same fingertip in both the first usage state and the second usage state, and hence the ease of use of the electronic apparatus is improved by a simple structure.

If the switching of the allocation of the inputting functions to the keys 21 is realized by rotating the key allocation arrangement of each of the first and second key groups 31, 32, 180°, it is possible to realize switching of the inputting functions by a relatively simple change in the arrangement.

The electronic apparatuses 1, 51, and 61 according to the first to third embodiments have been described above. However, the present invention is not limited to these. The constituent elements according to the first to third embodiments can be appropriately combined with each other so as to be applied.

In the first to third embodiments, the inputting functions of the keyboard section 6 corresponding to the fingertips are character inputting functions. However, the present invention is not limited to these. For example, functions of inputting numerals such as those of a ten-key pad, or other inputting functions such as those of function keys may be made to correspond to the fingertips. With such an electronic apparatus, the usability is improved as in the first embodiment.

If a key top face of each of the keys 21 according to each of the first to third embodiments is provided with an inscription of a character to which an inputting function is allocated in the second usage state, in addition to an inscription of a character to which an inputting function is allocated in the first usage state, the ease of use of the electronic apparatus is further improved. Furthermore, inputting functions to be allocated in the first and second usage states may be alternatively displayed by using, for example, LEDs or the like. Moreover, the embodiments of the present invention are also applicable to an electronic apparatus held with one hand to be used.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a main body unit;
a keyboard section provided on the main body unit, and including a plurality of keys to which inputting functions different from each other are allocated;
a display unit including a display screen; and
a hinge section rotatably coupling the display unit to an end part of the main body unit,
wherein
the electronic apparatus is switchable between a first usage state, in which the display unit is raised from the main body unit and the keyboard section is to be operable with the main body unit being placed on a desktop, and a second usage state, in which the main body unit and the display unit are folded back to back with each other, the electronic apparatus is to be held with both hands of a user with the display screen being directed to the user, and the keyboard section is exposed on a backside of the electronic apparatus and is to be operable with fingertips of the both hands, and
the keyboard section is constructed and arranged such that, when the electronic apparatus is used in the second usage state, the allocation of the inputting functions to the keys is electrically switched in such a manner that correspondence relationships between the fingertips and the inputting functions in the first usage state are maintained in the second usage state.

2. The electronic apparatus according to claim 1, wherein
in the second usage state, the electronic apparatus is used in a state where an end part opposite to the end part coupled to the hinge section is closer to the user than the end part coupled to the hinge section,
the keys of the keyboard section include a first key group for a left-hand operation, and a second key group for a right-hand operation, and
switching of the allocation of the inputting functions to the keys between the first usage state and the second usage state is performed by replacing a key allocation arrangement of the first key group and a key allocation arrangement of the second key group with each other.

3. The electronic apparatus according to claim 2, wherein
the first key group and the second key group are identical with each other in the number of keys and the mounting arrangement of the keys.

4. The electronic apparatus according to claim 3, wherein
the mounting arrangement of the first key group is symmetrical with respect to a straight line passing through the center of the first key group, and extending in a direction perpendicular to a longitudinal direction of the first key group, and
the mounting arrangement of the second key group is symmetrical with respect to a straight line passing through the center of the second key group, and extending in the direction perpendicular to a longitudinal direction of the second key group.

5. The electronic apparatus according to claim 2, wherein
each of the first and second key groups of the keyboard section is arranged oblique in such a manner that with an increase in the distance on the main body unit from the end part coupled to the hinge section toward the opposite end part, each of the first and second key groups becomes closer to a center portion of the main body unit.

6. The electronic apparatus according to claim 2, further comprising
an another key which is mounted in a region adjacent to the display screen at an end part of the display unit opposite to an end part thereof coupled to the hinge section.

7. The electronic apparatus according to claim 1, wherein
in the second usage state, the electronic apparatus is used in a state where the end part coupled to the hinge section is closer to the user than an end part opposite to the end part coupled to the hinge section,
the keys of the keyboard section include a first key group for a left-hand operation, and a second key group for a right-hand operation, and
switching of the allocation of the inputting functions to the keys between the first usage state and the second usage state is performed by rotating the key allocation arrangement of each of the first and second key groups 180°.

8. An electronic apparatus comprising:
a main body unit;
a keyboard section provided on the main body unit, and including a plurality of keys to which inputting functions different from each other are allocated;
a display unit including a display screen; and
a hinge section rotatably coupling the display unit to the main body unit,
wherein
the electronic apparatus is switchable between a first usage state, in which the display unit is raised from the main body unit and the keyboard section is to be operable with the main body unit being placed on a desktop, and a second usage state, in which the main body unit and the display unit are folded back to back with each other, the electronic apparatus is to be held with a hand of a user with the display screen being directed to the user, and the keyboard section is exposed on a backside of the electronic apparatus and is to be operable with fingertips of the hand, and
the keyboard section is constructed and arranged such that, when the electronic apparatus is used in the second usage state, the allocation of the inputting functions to the keys is electrically switched in such a manner that correspondence relationships between the fingertips and the inputting functions in the first usage state are maintained in the second usage state.
